(19) United States
(12) Patent Application Publication
(10) Pub. No.: US 2009/0104558 A1
(43) Pub. Date: Apr. 23, 2009

(54) Solution for a Treatment of a Resist, a Modified Resist, a Process for the Treatment of a Resist and an Intermediate Product

(76) Inventor: Klaus Elian, Alteglofsheim (DE)

Correspondence Address: SLATER & MATSIL, L.L.P., 17950 PRESTON ROAD, SUITE 1000, DALLAS, TX, 75252, US

(21) Appl. No.: 11/875,215

(22) Filed: Oct. 19, 2007

(51) Int. Cl. G03F 7/004; G03F 7/00

(52) U.S. Cl. 430/270.1; 430/331

(57) ABSTRACT

Solutions for the treatment of a resist used in the manufacturing of a semiconductor device or masks used in the manufacturing of semiconductor devices are described. Preferably, the solution includes a transition metal organic compound. Furthermore embodiments of modified resists, a process and an intermediate product are described.

### BACKGROUND

In the manufacturing of semiconductor devices photosensitive resists are used to structure material underneath the resist.

In the manufacturing of semiconductor devices it is known that a substrate, such as a mask blank comprising quartz glass, a silicon wafer, a germanium wafer or an III-V material wafer, can be covered with a resist in one process step in the structuring of the substrate. In the process of structuring, the resist can be subjected to some sort of radiation, e.g., electromagnetic radiation like UV or EUV. The radiation can also comprise particles such as electrons or other charged particles. Furthermore, it is possible for the resist to be structured using a mechanical imprint.

After the structuring, the resist can be baked (i.e., thermally heated) and can also be developed with a developer solution, such as aqueous alkaline solution. Further process steps can comprise rinsing process steps, e.g., with deionized water and post bake steps.

### DETAILED DESCRIPTION OF ILLUSTRATIVE EMBODIMENTS

In the following, various embodiments for a solution to be used in the processing of a resist are described. Furthermore, embodiments for a modified resist, a process using a solution and an intermediate product manufactured using a solution are described.

All these embodiments can be used with one or more of the above mentioned process steps for structuring a resist.

The solution that is used in the treatment of the resist comprises a transition metal organic compound. This solution can be used as reactive rinse solution. The transition metal organic compound binds selectively with certain components of the resist and renders the resist stable against etching. This can result in a reduced line edge roughness.

Examples for transition metal organic compounds can be titanium compounds, zirconium compounds or hafnium compounds. These transition metals are members of the fourth group of the periodic system. Combinations of two or more of the transition metal organic compounds are possible.

Examples for organic compounds comprising a transition metal are:

titanium(IV) ethoxide (titanium(IV) ethylate),

titanium(IV) tert-butoxide (titanium(IV) tert-butylate),

zirconium(IV) butylate (zirconium(IV) butoxide),

zirconium(IV) ethoxide,

zirconium(IV) propylate,

zirconium(IV) acetate hydroxide.

### Example 1

In the following an example involving titanium(IV) ethoxide (or titanium(IV)ethylate) in ethanolic solution is described:

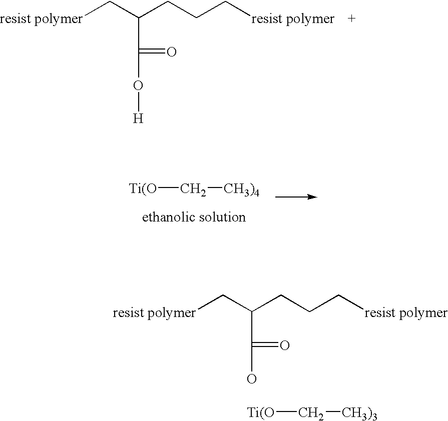

The reaction can take place at room temperature or temperatures between room temperature and 70° C. after a development process step of the resist.

The transition metal organic compound, here a titanium compound in a reactive rinse solution binds to a protection group of the resist that has already been decomposed in a partially illuminated region of the resist. After this reactive rinsing the resist is modified.

In another embodiment, the reaction takes place with the protection group itself:

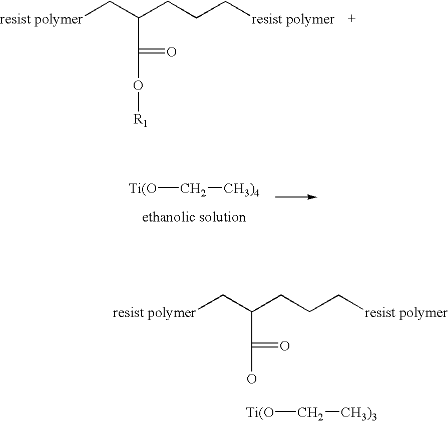

If a resist of a different type is used, e.g., a COMA type resist, the reaction of the transition metal organic compound, here a titanium compound can be a rather quick reaction with an anhydride function:

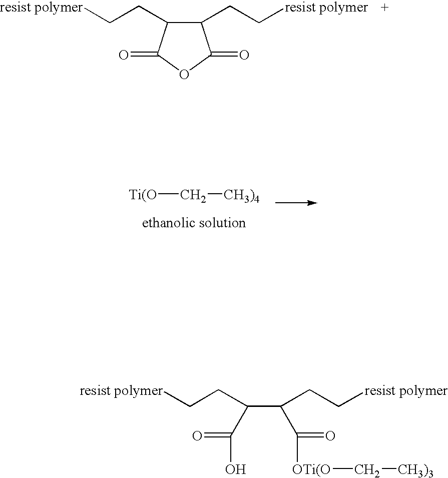

All these embodiments can be reactions after the development process step.

### Example 2

Another embodiment of a metal transition organic compound in a solution is titanium(IV) tert-butoxide (titanium(IV) tert-butylate):

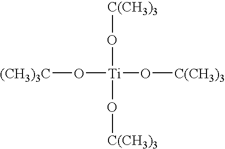

Alternatively the analog compound with hafnium instead of titanium can be used.

This compound can be applied to a resist in an alcohol solution after a development process step.

### Example 3

Another embodiment of a metal transition organic compound in a solution is zirconium(IV) butylate (zirconium butoxide):

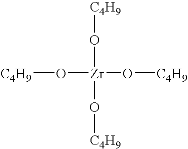

This compound can be applied to a resist in an alcohol solution after a development process step.

### Example 5

Another embodiment of a metal transition organic compound in a solution is zirconium(IV) ethoxide or zirconium(IV) propylate.

These compounds can be applied to a resist in an alcohol solution after a development process step.

The transition metal organic compounds of the examples 1 to 5 are soluble in organic solvents so that they can be used in a post development process.

### Example 6

Zirconium(IV) acetate hydroxide compound with the general composition (CH₃CO₂)ₓZr(OH)_{y} with x=2 and y=2 as in the following example are stable in water so that they can be used in connection with developer solutions; if necessary in connection with tensides.

An example of a zirconium(IV) acetate hydroxide with x=2 and y=2 is:

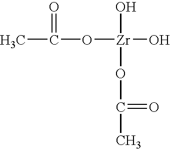

In a solution applied to a resist, this compound can bind to a —COOH group of the resist, so that COO—Zr+H₂O results. This transition metal organic compound can be used in connection with an alkaline developer solution.

Furthermore, this compound can be used in connection with TMAH developer solution without affecting the developing process. This compound binds to already developed (i.e., reacted) structures in the resist with a high carboxylic acid content and not (or much slower) to the unilluminated and undeveloped bulk resist material.

If necessary, tensides can be used in a rinse solution using this transition metal organic compound.

### Example 7

In another embodiment a zirconium(IV) tert-butylate:

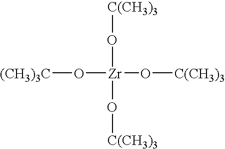

can also be used in a water solution of a developer solution since it is not sensitive to water.

Since the transition metal organic compounds in the embodiments of examples 6 and 7 are soluble in water, they can be used in an in-situ development and/or metallizing process.

The examples 1 to 7 describe different embodiments for a solution comprising transition metal organic compound, in particular compounds comprising a metal from the fourth group of the periodic system.

The person skilled in the art will recognize that these embodiments are just representative for a larger class of compounds that can be used in a solution for the treatment of a resist or in a treatment of a resist.

Possible reaction mechanisms of these embodiments comprise the binding to a carbonyl group in the resist. This can occur, e.g., in the following ways:

a) The resist comprises carboxylic acids to some extent. The concentration is higher in partially illuminated regions at the margin of the resist structures due to the products of decomposed protection groups. The transition metal organic compound can react with the carbonyl group of the carboxylic acid.

b) The reaction can take place with carboxylic anhydride groups, which are especially present in COMA-type ArF resists. COMA stands for cycloolefine maleic anhydride type resists. The maleic anhydride is an active reaction partner for the subsequent reactions. ArF is a plasma generating a 193 nm wave length.

c) The reaction can take place with esters of carboxylic acid or alkylesteroxy-carbonyloxy groups, i.e., with the protective groups themselves.

As a end product in most cases (as shown above) an ester of carboxylic acid of the transition metal organic compound or a direct binding of the transition metal organic compound to the carbonyl group results.

In the following an embodiment for a process involving transition metal organic compounds is given as an example. Naturally the process and the substances can be used in connection with other substrates, like silicon or other wafers.

Step 1: Synthesis of a Resist Polymer:

The polymer is synthesised using a radical polymerization. To that effect

20.5 g (209 mmol) maleic anhydride,

23.8 g (167 mmol) tert-butylmethacrylate,

3.3 g (21 mmol) methacrylic acid,

2.4 g (21 mmol) allyltrimethylsilane,

0.69 g (4.2 mmol) a,a′-azoisobutyronitrile as radical starter and

0.34 g (1.7 mmol) dodecylmercaptan as chain regulator

are dissolved in 40 g (50 ml) 2-butanone and are heated to boiling (80° C.) for 3 hours under reflux.

Subsequently 4.0 g (5.0 ml) methanol (for the partial alcoholysis of the anhydride) is added. The reaction mixture is heated for further 24 hours to boiling (80° C.) under reflux.

The reaction mixture is then cooled to room temperatures. Under vigorous stirring 35.0 g (27.5 ml) 2-propanol is added.

The resulting solution is dripped within 30 minutes under very vigorous mechanical stirring into a solution of

10.5 g (13.1 ml) 2-butanone,

337.0 g (429 ml) 2-propanol and

329.0 g (329.0 ml) water,

during this the polymer precipitates as fine white powder. The stirring continues for further 30 minutes and then the solvent is then drawn off over a G4 frit under slightly reduced pressure.

The white precipitation is washed with a solution of:

16.0 g (20.0 ml) 2-butanon,

111.0 g (141 ml) 2-propanol and

100.0 g (100 ml) water.

and then dried for 72 hours at 80° C. under high vacuum.

This results in approximately 40 g fine white powder as reaction product.

Preparation of the resist: 8% (w/w) of the polymer (preparation as described above) are dissolved with 5% (w/w) (relative to the solid polymer) triphenylsulfonium hexafluoropropanesulfonate in 92% (w/w) 1-methoxy-2-propylacetate.

Step 2: Application of the Resist on the Substrate

In this exemplary embodiment the substrate is a mask blank, comprising a quartz glass. The mask blank has a thickness of 2 mm and is sputtered with a chrome layer. As bottom resist a commercial resist (e.g., Novolac with 2-methoxypropylacetate as solvent, TOK BLC001) is applied with a spin coating process at 2000 rpm for 20 seconds.

Subsequent heating to 110° C. for 90 seconds evaporates the solvent. Further heating to 235° C. for 90 seconds results in crosslinking of the novolac. The result is an approximately 500 nm thick novolac layer with a high chemical resistivity.

The resist prepared under process step 1 is now applied with a spin coating process at 2000 rpm for 20 seconds as the upper layer on the bottom resist. Subsequent heating to 140° C. for 60 seconds evaporates the solvent. The result is a solid photoresist layer.

Step 3: Structuring of the Mask Blank with an E-Beam Process

In the present embodiment, the resist layer is structured using an electron beam. In this case, e.g., the resist on the quartz blank is structured with a test layout (line and trench pattern of varying dimensions 350 nm to 100 nm, using different doses 3 μC/cm² to 37 μC/cm²) using a Jeol JSM840/Sietec Nanobeam pattern-generator at 40 keV.

Subsequently the probe is heated to 140° C. for 60 seconds. At this temperature the chemical amplification reaction takes place.

The irradiation with electrons results in the creation of acid protons which react in a catalytic reaction with the solution-inhibitors. This is a positive resist process. Non-polar polymer chains or polymer fragments are transformed into polar polymer chain or polymer fragments which can be developed in further process steps.

Step 4: Development of the Resist:

In the following developer process step the polar polymer chains or polymer fragments are removed by the aqueous alkaline developer. To facilitate this, the mask blank is treated with a commercial developer on tetramethylammoniumhydroxide basis (TMA 238 WA by JSR) in a puddle process or a dipping process.

The developing time is one minute. Afterwards the mask blank is rinsed for 20 seconds with water and is blow dried using nitrogen. The result is a three dimensional image of the layout written in step 3 in the upper resist layer.

Step 5: Treatment with a Solution Comprising a Transition Metal Organic Compound

The developed mask blank is treated for 60 seconds with a reactive rinse solution consisting of 2% (w/w) titanium(IV) ethoxide and und 98% (w/w) 1-hexanol. This treatment can be performed in puddle process in a commercial development tool or in a dipping process for organic solvents.

It is possible to use benzene, butanol or acetonitrile as solvents.

Subsequently the mask blank is rinsed 20 seconds with isopropanol and is blow dried with nitrogen.

During this titanization step, the upper layer of the resist is enriched with titanium which bonded chemically stable into the resist. Thus, the resist becomes a modified resist.

The titanium provides a very high stability for the following plasma etch process step.

The person skilled in the art will recognize that instead of titanium(IV) ethoxide other transition metal organic compounds can be used, e.g., hafnium or zirconium based compounds.

Furthermore, the person skilled in the art will recognize that the use of the solution comprising a transition metal organic compound is not restricted to the process steps outlined above and below. The use of the solution in a rinsing process is in principle independent from other process steps, provided the solution is applied to a suitable resist.

Other organic solvents can be alcohols, ethanols, esters, ketones, esters having a strongly polar group or ketones having a strongly polar group.

Step 6: Structuring of the Bottom Resist and the Chrome

The structuring of the chrome layer is effected with known plasma etch process equipment using an oxygen/halogen based etch chemistry. Using this, the bottom resist layer as well as the chrome layer is removed in those regions which are not protected by the upper resist layer.

This embodiment of the process is applied to the manufacturing of a mask to be used in the manufacturing of a semiconductor device or in the manufacturing of masks used in the manufacturing of semiconductor devices. Examples for semiconductor devices are microprocessors, memory chips, DRAM chips, bio chips, microelectromechanical devices.

Another embodiment of the process also using a reactive rinse solution with a transition metal organic compound can be used to structure a wafer made from silicon, germanium or a III-V material. The substrate can be prestructured in any case.

What is claimed is:

1. A solution for the treatment of a resist used in the manufacturing of a semiconductor device or masks used in the manufacturing of semiconductor devices, wherein the solution comprises a transition metal organic compound.

2. The solution according to claim 1, wherein the transition metal organic compound comprises a compound with least one of the group of titanium, zirconium and/or hafnium.

3. The solution according to claim 2, wherein the compound comprises at least one of the group of titanium(IV) ethoxide, titanium(IV) tert-butoxide, zirconium(IV) butoxide, zirconium(IV) ethoxide, zirconium(IV) propylate and/or zirconium(IV) acetate hydroxide.

4. The solution according to claim 1, further comprising an organic solvent.

5. The solution according to claim 4, wherein the organic solvent comprises a solvent selected from the group consisting of alcohol, ethanol, ester, ketone, ester having strongly polar group and ketone having strongly polar group.

6. The solution according to claim 1, further comprising at least one tenside.

7. The solution according to claim 1, further comprising at least one short chained epoxy compound having alkyl chains with less or equal than 10 C-atoms.

8. A modified resist comprising a transition metal organic compound bound to a carbonyl group of a resist polymer.

9. The modified resist according to claim 8, wherein the transition metal organic compound comprises a compound with least one of the group of titanium, zirconium and/or hafnium.

10. The modified resist according to claim 9, wherein the compound comprises at least one of titanium(IV) ethoxide, titanium(IV) tert-butoxide, zirconium(IV) butoxide, zirconium(IV) ethoxide, zirconium(IV) propylate and/or zirconium(IV) acetate hydroxide.

11. The modified resist according to claim 8, comprising a metal organic compound bound to at least one of the group of carboxyclic acid, carboxylic anhydride groups, esters of carboxylic acid and/or alkylesteroxy-carbonyloxy groups.

12. The modified resist according to claim 8, comprising at least an ester of a carboxylic acid of the transition metal compound or a direct binding of the transition metal to the carbonyl group of the resist.

13. A process for the treatment of a resist in the manufacturing of a semiconductor device or in the manufacturing of a mask, wherein at least a region of a resist is treated with a solution comprising a transition metal organic compound.

14. The process according to claim 13, wherein the solution comprises a compound with least one of the group of titanium, zirconium and/or hafnium.

15. The process according to claim 13, wherein the solution comprises at least one compound comprising a transition metal, the compound being one of the group of titanium(IV)ethoxide, titanium(IV) tert-butoxide, zirconium(IV) butoxide, zirconium(IV) ethoxide, zirconium(IV) propylate and/or zirconium(IV) acetate hydroxide.

16. The process according to claim 13, comprising at least one solvent from the group of water and an organic solvent.

17. The process according to claim 16, wherein the at least one solvent comprises ethanol and/or alcohol.

18. The process according to claim 13, wherein the solution comprises at least one tenside.

19. The process according to claim 13, wherein the solution is applied to the at least one region of the resist after application of the resist on a substrate or after a structuring of the resist.

20. The process according to claim 13, wherein, after application of the solution, the resist is subjected to a thermal treatment.

21. The process according to claim 13, wherein the treatment with the solution is performed in-situ in a resist development process step.

22. The process according to claim 13, wherein the treatment with the solution is performed in-situ in a post resist development process step or a metallization process step.

23. An intermediate product in the manufacturing of a semiconductor device or in the manufacturing of a mask, the intermediate product comprising a substrate which is at least partially covered by a resist treated by a solution comprising at least one transition metal organic compound.

24. The intermediate product according to claim 23, wherein the resist at least partially comprises an ester of a carboxylic acid of the transitional metal organic compound or a chemical bond between a carbonyl group of the resist and the transition metal organic compound.

25. The intermediate product according to claim 23, wherein the substrate comprises a silicon wafer, a germanium wafer, a III-V material wafer, a quartz glass substrate or a chrome on glass substrate.
